(19) United States
(12) Patent Application Publication
(10) Pub. No.: US 2008/0068695 A1
(43) Pub. Date: Mar. 20, 2008

(54) Tracing Method And Apparatus

(75) Inventors: Takao Ozaki, Kanagawa-ken (JP); Yoji Okazaki, Kanagawa-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Minato-ku, Tokoyo (JP)

(21) Appl. No.: 11/665,494

(22) PCT Filed: Oct. 13, 2005
(86) PCT No.: PCT/JP05/19246

§ 371 Date: Apr. 16, 2007

(30) Foreign Application Priority Data
Oct. 15, 2004 (JP) 2004-302283

(51) Int. Cl. G02B 26/08; G03F 7/00

(52) U.S. Cl. 359/223; 430/30

(57) ABSTRACT

A tracing method in which tracing is performed by moving a spatial optical modulation device in a predetermined scanning direction relative to a tracing surface is provided. The spatial optical modulation device includes multitudes of tracing elements for modulating inputted light according to control signals transferred in accordance with tracing information. The method allows the spatial optical modulation device to perform the modulation rapidly to reduce the tracing time. The special modulation device is divided into a plurality of blocks A to D, and the control signals for each of the blocks A to D are transferred to the blocks in parallel.

### TECHNICAL FIELD

The present invention relates to a tracing method and apparatus in which tracing is performed by moving a spatial optical modulation device in a predetermined scanning direction relative to a tracing surface, the spatial optical modulation device including multitudes of tracing elements for modulating inputted light according to control signals transferred in accordance with tracing information.

### BACKGROUND ART

Various types of tracing devices are known, in which an intended two-dimensional pattern is produced on a tracing surface based on image data.

As such kind of tracing devices, various types of photolithography machines for performing photolithography by modulating a light beam according to image data using a spatial modulation device, such as a digital micro-mirror device (DMD) or the like are proposed, as described for example, in Japanese Unexamined Patent Publication No. 2004-233718. The DMD is constituted by multitudes of tiny micro-mirrors arranged two-dimensionally (L rows×M columns) on memory cells (SRAM arrays) formed on a semiconductor substrate made of, for example, silicon or the like, and the angle of the reflection surface of the mirror is changed by tilting the mirror through controlling electrostatic force provided by the charges stored in the memory cell. The photolithography is performed by scanning the DMD in a predetermined direction along the exposing surface.

Here, in the DMD described above, image data are transferred to the SRAM arrays first, then each of the micro-mirrors is reset, that is, each of the micro-mirrors is tilted by a predetermined angle (“ON” or “OFF”) in accordance with the content (“0” or “1”) of the image data written in the SRAM arrays, thereby the light is reflected to different directions.

But, heretofore, the DMD has been driven by the method in which image data are sequentially transferred to the SRAM arrays and written therein on a row by row basis, and resetting is implemented after image data for all of the rows are transferred to the SRAM arrays. This has required an extended time to transfer the image data, resulting in a slow modulation speed and extend overall time for the photolithography. Further, high-resolution photolithography has been difficult due to the slow modulation speed.

In view of the circumstances described above, it is an object of the present invention to provide a tracing method and apparatus that allows the spatial optical modulation device to perform the modulation rapidly.

### DISCLOSURE OF INVENTION

The first tracing method of the present invention is a tracing method using a spatial optical modulation device constituted by multitudes of tracing elements disposed thereon two-dimensionally for modulating inputted light according to control signals transferred in accordance with tracing information, in which tracing is performed by implementing the modulation through transferring the control signals to the tracing elements of the spatial optical modulation device, and moving the spatial optical modulation device in a predetermined scanning direction relative to a tracing surface, wherein:

the spatial optical modulation device is divided into a plurality of blocks in the scanning direction; and

the control signals for each of the plurality of blocks are transferred thereto in parallel.

In the tracing method described above, the arrangement of each of trace regions on the tracing surface corresponding to each of the blocks may be controlled by causing the modulation to be implemented independently by each of the blocks, and controlling the timing of the modulation implemented independently by each of the blocks, and/or the relative moving speed of the spatial optical modulation device in the scanning direction.

Further, the tracing may be performed first by the block disposed downstream in the scanning direction, then by the block or blocks disposed upstream with respect to the tracing surface.

Still further, the timing of the modulation implemented independently by each of the blocks, and/or the relative moving speed of the spatial optical modulation device in the scanning direction may be controlled such that the trace region corresponding to the block disposed downstream, and the trace region or regions corresponding to the block or blocks disposed upstream in the scanning direction with respect to the tracing surface are overlap with each other.

Further, the timing of the modulation implemented independently by each of the blocks, and/or the relative moving speed of the spatial optical modulation device in the scanning direction maybe controlled such that trace points in the trace region or regions corresponding to the block or blocks disposed upstream are disposed between trace points arranged in the scanning direction in the trace region corresponding to the block disposed downstream in the scanning direction with respect to the tracing surface.

Still further, the timing of the modulation implemented independently by each of the blocks, and/or the relative moving speed of the spatial optical modulation device in the scanning direction may be controlled such that trace points in each of the trace regions corresponding to each of the blocks are disposed at regular intervals in the scanning direction.

Further, each of the blocks may be further subdivided into a plurality of segments, and the control signals may be sequentially transferred to each of the segments in each of the blocks, and the modulation may be implemented sequentially by each of the segments from the time when each of the transfers of the control signals is completed.

Still Further, arrangement of each of segment trace regions on the tracing surface corresponding to each of the segments in each of the blocks may be controlled by controlling the timing of the modulation in the segments in each of the blocks, and/or the relative moving speed of the spatial optical modulation device in the scanning direction.

Further, the tracing may be performed first by the segments in the block disposed downstream, then by the segments in the block or blocks disposed upstream in the scanning direction with respect to the tracing surface.

Still further, the timing of the modulation in the segments in each of the blocks, and/or the relative moving speed of the spatial optical modulation device in the scanning direction may be controlled such that the segment trace regions corresponding to the segments in the block disposed downstream, and the segment trace regions corresponding to the segments in the block or blocks disposed upstream in the scanning direction with respect to the tracing surface are overlap with each other.

Further, the timing of the modulation in the segments in each of the blocks, and/or the relative moving speed of the spatial optical modulation device in the scanning direction may be controlled such that trace points in the segment trace regions corresponding to the segments in the block or blocks disposed upstream are disposed between trace points arranged in the scanning direction in the segment trace regions corresponding to the segments in the block disposed downstream in the scanning direction with respect to the tracing surface.

Still further, the timing of the modulation in the segments in each of the blocks, and/or the relative moving speed of the spatial optical modulation device in the scanning direction may be controlled such that trace points in each of the segment trace regions corresponding to each of the segments in each of the blocks are disposed at regular intervals in the scanning direction.

Further, the number of segments N in each of the blocks may be set to satisfy the following formula.
N=Tₛᵣ/Tₜᵣ
where: Tₜᵣ: modulation time of each segment
   Tₛᵣ: transfer time of control signals to each segment

The second tracing method of the present invention is a tracing method using a spatial optical modulation device constituted by multitudes of tracing elements disposed thereon two-dimensionally for modulating inputted light according to control signals transferred in accordance with tracing information, in which tracing is performed by implementing the modulation through transferring the control signals to the tracing elements of the spatial optical modulation device, and moving the spatial optical modulation device in a predetermined scanning direction relative to a tracing surface, wherein:

the spatial optical modulation device is divided into a plurality of blocks; and

the control signals for each of the plurality of blocks are transferred thereto in parallel.

The first tracing apparatus of the present invention is a tracing apparatus comprising:

a spatial optical modulation device constituted by multitudes of tracing elements disposed thereon two-dimensionally for modulating inputted light according to control signals transferred in accordance with tracing information;

a moving means for moving the spatial optical modulation device in a predetermined scanning direction relative to a tracing surface; and

a control means for causing the tracing elements of the spatial optical modulation device to implement the modulation by transferring the control signals thereto, and controlling the relative moving speed of the spatial optical modulation device in the scanning direction through controlling the moving means, wherein:

the spatial optical modulation device is divided into a plurality of blocks in the scanning direction; and

the control means includes a plurality of control signal transfer sections, each being provided for each of the blocks, for transferring the control signals to each of the blocks in parallel.

In the tracing apparatus described above, the control section may be configured to control the arrangement of each of trace regions on the tracing surface corresponding to each of the blocks by causing the modulation to be implemented independently by each of the blocks, and controlling the timing of the modulation implemented independently by each of the blocks, and/or the relative moving speed of the spatial optical modulation device in the scanning direction.

Further, the control section may be configured to cause the tracing to be performed first by the block disposed downstream, then by the block or blocks disposed upstream in the scanning direction with respect to the tracing surface.

Still further, the control section may be configured to control the timing of the modulation implemented independently by each of the blocks, and/or the relative moving speed of the spatial optical modulation device in the scanning direction such that the trace region corresponding to the block disposed downstream, and the trace region or regions corresponding to the block or blocks disposed upstream in the scanning direction with respect to the tracing surface are overlap with each other.

Further, the control section may be configured to control the timing of the modulation implemented independently by each of the blocks, and/or the relative moving speed of the spatial optical modulation device in the scanning direction such that trace points in the trace region or regions corresponding to the block or blocks disposed upstream are disposed between trace points arranged in the scanning direction in the trace region corresponding to the block disposed downstream in the scanning direction with respect to the tracing surface.

Still further, the control section may be configured to control the timing of the modulation implemented independently by each of the blocks, and/or the relative moving speed of the spatial optical modulation device in the scanning direction such that trace points in each of the trace regions corresponding to each of the blocks are disposed at regular intervals in the scanning direction.

Further, each of the blocks may be further subdivided into a plurality of segments, and the control signals may be sequentially transferred to each of the segments in each of the blocks, and the modulation may be implemented sequentially by each of the segments from the time when each of the transfers of the control signals is completed.

Still further, the control section may be configured to control arrangement of each of segment trace regions on the tracing surface corresponding to each of the segments in each of the blocks by controlling the timing of the modulation in the segments in each of the blocks, and/or the relative moving speed of the spatial optical modulation device in the scanning direction.

Further, the control section may be configured to cause the tracing to be performed first by the segments in the block disposed downstream, then by the segments in the block or blocks disposed upstream in the scanning direction with respect to the tracing surface.

Still further, the control section may be configured to control the timing of the modulation in the segments in each of the blocks, and/or the relative moving speed of the spatial optical modulation device in the scanning direction such that the segment trace regions corresponding to the segments in the block disposed downstream, and the segment trace regions corresponding to the segments in the block or blocks disposed upstream in the scanning direction with respect to the tracing surface are overlap with each other.

Further, the control section may be configured to control the timing of the modulation in the segments in each of the blocks, and/or the relative moving speed of the spatial optical modulation device in the scanning direction such that trace points in the segment trace regions corresponding to the segments in the block or blocks disposed upstream are disposed between trace points arranged in the scanning direction in the segment trace regions corresponding to the segments in the block disposed downstream in the scanning direction with respect to the tracing surface.

Still further, the control section may be configured to control the timing of the modulation in the segments in each of the blocks, and/or the relative moving speed of the spatial optical modulation device in the scanning direction such that trace points in each of the segment trace regions corresponding to each of the segments in each of the blocks are disposed at regular intervals in the scanning direction.

Further, the number of segments N in each of the blocks may be set to satisfy the following formula.
N=Tₛᵣ/Tₜᵣ
where: Tₜᵣ: modulation time of each segment
   Tₛᵣ: transfer time of control signals to each segment

Here, the referent of “control signals for each of the plurality of blocks are transferred thereto in parallel” as used herein means that the control signals for at least two blocks are transferred simultaneously at least at a predetermined time point, and may include the case where there is a predetermined time difference between the start timings of transferring the control signals to the respective blocks, as well as the case where the control signals are transferred to the respective blocks at the same start timing.

The referent of “divided in the scanning direction” as used herein means that where either of the two orthogonal directions to which the tracing elements are disposed corresponds to the scanning direction, the division is made in that direction, and where neither of the two orthogonal directions corresponds to the scanning direction, the division is made in the direction that forms a smaller tilt angle with the scanning direction.

The second tracing apparatus of the present invention is a tracing apparatus comprising:

a spatial optical modulation device constituted by multitudes of tracing elements disposed thereon two-dimensionally for modulating inputted light according to control signals transferred in accordance with tracing information;

a moving means for moving the spatial optical modulation device in a predetermined scanning direction relative to a tracing surface; and

a control means for causing the tracing elements of the spatial optical modulation device to implement the modulation by transferring the control signals thereto, and controlling the relative moving speed of the spatial optical modulation device in the scanning direction through controlling the moving means, wherein:

the spatial optical modulation device is divided into a plurality of blocks; and

the control means includes a plurality of control signal transfer sections, each being provided for each of the blocks, for transferring the control signals to each of the blocks in parallel.

According to the first tracing method and apparatus of the present invention, the spatial optical modulation device is divided into a plurality of blocks in the scanning direction, and the control signals for each of the plurality of blocks are transferred thereto in parallel, so that the modulation speed may be increased compared with the case where image data are sequentially transferred to the SRAM arrays and written therein on a row by row basis, and resetting is performed after image data for all of the rows are transferred to the SRAM arrays as in the traditional method. For example, if the spatial optical modulation device is divided into four blocks, the modulation speed may be quadrupled.

Further, in the tracing method and apparatus described above, when arrangement of each of trace regions on the tracing surface corresponding to each of the blocks is controlled by causing the modulation to be implemented independently by each of the blocks, and controlling the timing of the modulation implemented independently by each of the blocks, and/or the relative moving speed of the spatial optical modulation device in the scanning direction, arrangement of each of the trace regions on the tracing surface corresponding to each of the blocks may be controlled at will. For example, trace points in each of the trace regions corresponding to each of the blocks may be disposed at regular intervals in the scanning direction, which results in uniformly distributed resolution.

Further, when each of the blocks is further subdivided into a plurality of segments in the scanning direction, and the control signals are transferred sequentially to each of the plurality of segments, and the modulation is implemented sequentially when each of the transfers of the control signals is completed in each of the blocks, then, while one of the segments is being reset, control signal transfers to other segments may be implemented in each of the blocks. This allows the modulation speed of each of the blocks to be further enhanced. For example, if each of the blocks is subdivided into three segments, the modulation speed may be further tripled, so that the modulation speed may be twelve fold by combining the division of the spatial optical modulation device into blocks and division of each of the blocks into segments compared with the conventional method when a same resolution is assumed.

Still further, trace points in each of the segments may be produced during the modulation time in each of the blocks, so that the resolution may be improved. For example, if each of the blocks is subdivided into three segments, the resolution may be tripled.

### BRIEF DESCRIPTION OF DRAWINGS

FIG. 1 is a perspective view of a photolithography machine that employs an embodiment of the tracing apparatus of the present invention, illustrating the appearance thereof.

FIG. 2 is a perspective view of a scanner used in the photolithography machine shown in FIG. 1, illustrating the configuration thereof.

FIG. 3A is a plan view of a photosensitive material, illustrating exposed regions formed thereon.

FIG. 3B is a drawing illustrating the disposition of exposing area of each of the exposing heads.

FIG. 4 is a partial enlarged view of a DMD used in the photolithography machine shown in FIG. 1, illustrating the configuration thereof.

FIG. 5A is a perspective view of a DMD, illustrating the operation thereof.

FIG. 5B is a perspective view of a DMD, illustrating the operation thereof.

FIG. 6 is a drawing illustrating blocks on a DMD.

FIG. 7 is a schematic block diagram of control signal transfer sections, each provided for each of the blocks.

FIG. 8A is a drawing illustrating the timings of control signal transfer and modulation in each of the blocks.

FIG. 8B is a drawing illustrating example trace points when tracing is performed at the timings shown in FIG. 8A.

FIG. 9 is a drawing illustrating another example of the timings of control signal transfer and modulation in each of the blocks.

FIG. 10A is a drawing illustrating the timings of control signal transfer and modulation in each of the segments in each of the blocks.

FIG. 10B is a drawing illustrating example trace points when tracing is performed at the timings shown in FIG. 10A.

FIG. 11 is a drawing illustrating another example of the timings of control signal transfer and modulation in each of the segments in each of the blocks.

FIG. 12A is a drawing illustrating the timings of control signal transfer and modulation in a conventional photolithography machine.

FIG. 12B is a drawing illustrating example trace points when tracing is performed at the timings shown in FIG. 12A.

### BEST MODE FOR CARRYING OUT THE INVENTION

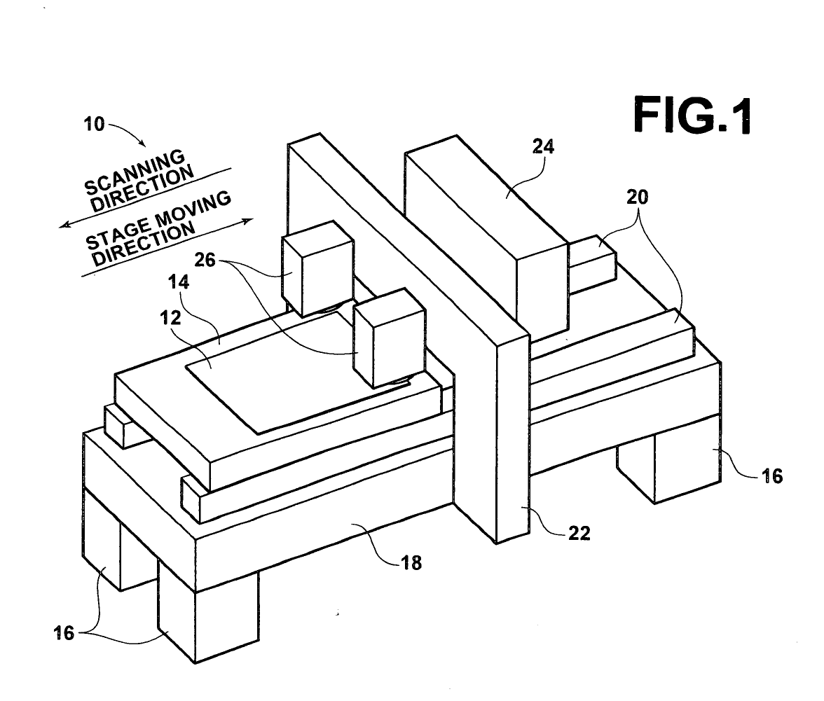

Hereinafter, a photolithography machine that employs a first embodiment of the tracing method and apparatus of the present invention will be described in detail with reference to accompanying drawings. The photolithography machine of the present embodiment uses a spatial optical modulation device constituted by multitudes of tracing elements disposed thereon two-dimensionally in orthogonal directions for modulating inputted light according to control signals transferred thereto, which has distinctive features in the method of transferring the control signals to the spatial optical modulation device. But, the overall configuration of the photolithography machine of the present embodiment will be described first. FIG. 1 is a perspective view of the photolithography machine of the present embodiment illustrating the schematic configuration thereof.

As shown in FIG. 1, the photolithography machine 10 of the present embodiment includes a plate-like moving stage 14 for holding a sheet-like photosensitive material 12 thereon by suction. Two guides 20 extending along the moving direction of the stage are provided on the upper surface of a thick plate-like mounting platform 18 which is supported by four legs 16. The stage 14 is arranged such that its longitudinal direction is oriented to the moving direction of the stage, and movably supported by the guides 20 to allow back-and-forth movements.

An inverse U-shaped gate 22 striding over the moving path of the stage 14 is provided at the central part of the mounting platform 18. Each of the ends of the inverse U-shaped gate 22 is fixedly attached to each of the sides of the mounting platform 18. A scanner 24 is provided on one side of the gate 20, and a plurality of sensors 26 (e.g. two) for detecting the front and rear edges of the photosensitive material 12 is provided on the other side. The scanner 24 and sensors 26 are fixedly attached to the gate 22 over the moving path of the stage 14. The scanner 24 and sensors 26 are connected to a control section that controls them, which will be described later.

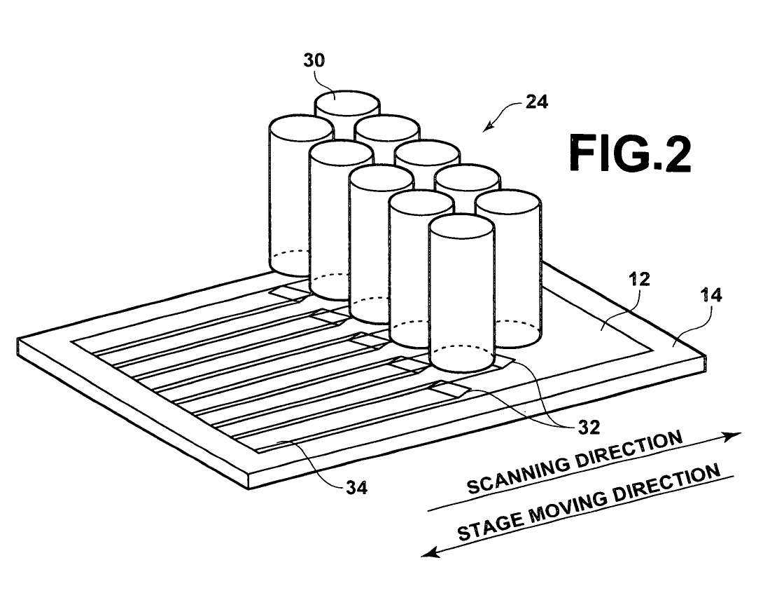

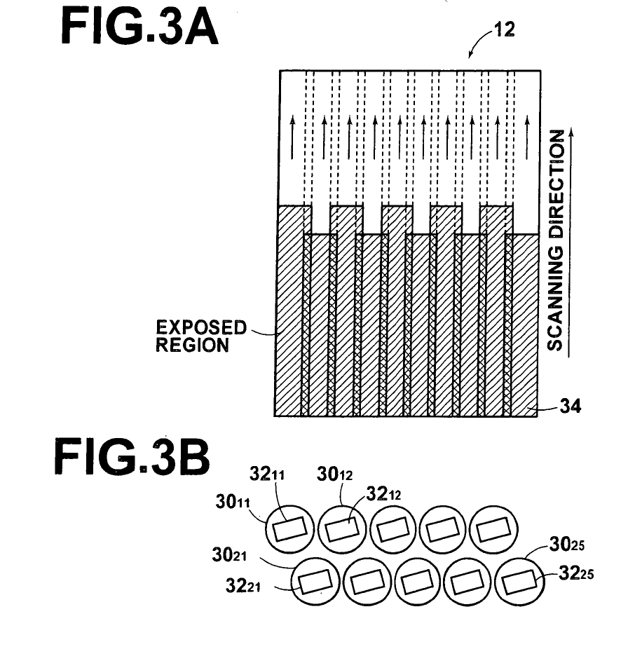

As shown in FIGS. 2 and 3B, the scanner 24 has ten exposing heads disposed in substantially a matrix form of two rows with five columns. Hereinafter, the exposing head disposed at the n^{th} column of the m^{th} row will be designated as the exposing head 30ₘₙ.

Each of the exposing heads 30 includes a digital micro-mirror device (DMD) 36, which is the spatial optical modulation device. The DMD 36 includes micro-mirrors serving as the tracing elements disposed thereon two-dimensionally in orthogonal directions. The DMD 36 is attached to each of the exposing heads 30 such that the direction in which the micro-mirrors are disposed forms a predetermined tilt angle θ with the scanning direction. Accordingly, exposing area 32 of each of the exposing heads 30 has a rectangular shape which is tilted with respect to the scanning direction as shown in FIG. 3B. Hereinafter, the exposing area of the exposing head disposed at the n^{th} column of the m^{th} array will be designated as the exposing area 32ₘₙ.

A fiber array light source (not shown) with the luminous points being arranged linearly in the direction corresponding to the direction of the long side of the exposing area 32, and a condenser lens system (not shown) for collimating the laser beams outputted from the fiber array light source and focusing the collimated laser beams on the DMD 36, after the collimated laser beams are corrected to provide uniformly distributed luminous energies, are provided on the light entry side of the DMD 36.

An imaging lens system (not shown) for focusing an image on the photosensitive material 120 is disposed on the light reflecting side of the DMD 36.

As shown in FIG. 3A, a stripe-shaped exposed region 34 is formed on the photosensitive material 12 by each of the exposing heads 30 as the stage 14 moves. Each of the exposing heads 30 arranged linearly in a row is displaced by a predetermined distance in the arranging direction from each of the corresponding exposing heads 30 arranged linearly in another row such that each of the stripe-shaped exposed regions 34 partly overlaps with the adjacent exposed regions 34. Consequently, the unexposed portion of the photosensitive material which corresponds to the space between the exposing areas 32₁₁ and 32₁₂ in the first row may be exposed by the exposing area 32₂₁ in the second row.

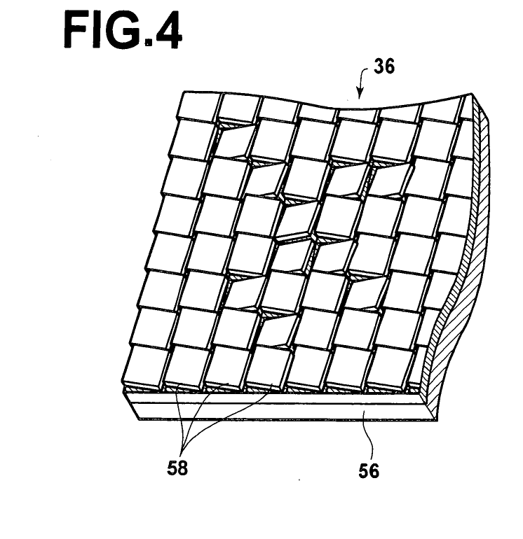

The DMD 36 includes micro-mirrors 58, each supported by a support post on a SRAM of SRAM arrays (memory cell) 56 as shown in FIG. 4. It is a mirror-device constituted by a multitude (e.g., 13.68 μm pitch, 1024×768) of micro-mirrors 58 forming pixels are disposed two dimensionally in orthogonal directions. As described above, silicon-gate CMOS SRAM arrays 56, which may be produced by a manufacturing line for general semiconductor memories, are provided beneath the micro-mirrors 58 through the support posts, each including a hinge and yoke.

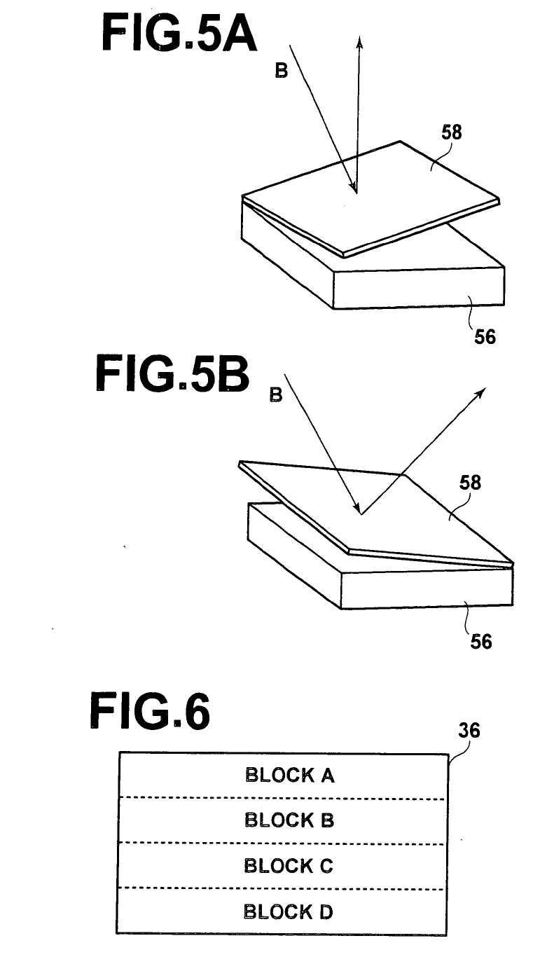

When digital signals serving as control signals are written into the SRAM arrays 56 of the DMD 36, a control voltage is applied to an electrode section (not shown) of each of the micro-mirrors 58 in accordance with the digital signal. Then, each of the micro-mirrors 58 supported by each of the support post is tilted within the range of ±α degrees (e.g., ±10 degrees) centered on the diagonal line by the electrostatic force developed by the applied voltage. FIG. 5A shows one of the micro-mirrors 58 tilted by +α degrees, which means that it is in on-state, and FIG. 5B shows one of the micro-mirrors 58 tilted by −α degrees, which means that it is in off-state. The light beam B inputted to one of the micro-mirrors 58 when it is in on-state is reflected toward the photosensitive material 12, and the light beam B inputted to one of the micro-mirrors 58 when it is in off-state is reflected toward a light absorption material other than the photosensitive material 12.

Here, the DMD 36 of the photolithography machine of the present embodiment is divided into four blocks A to D, each including a plurality of micro-mirrors, as shown in FIG. 6.

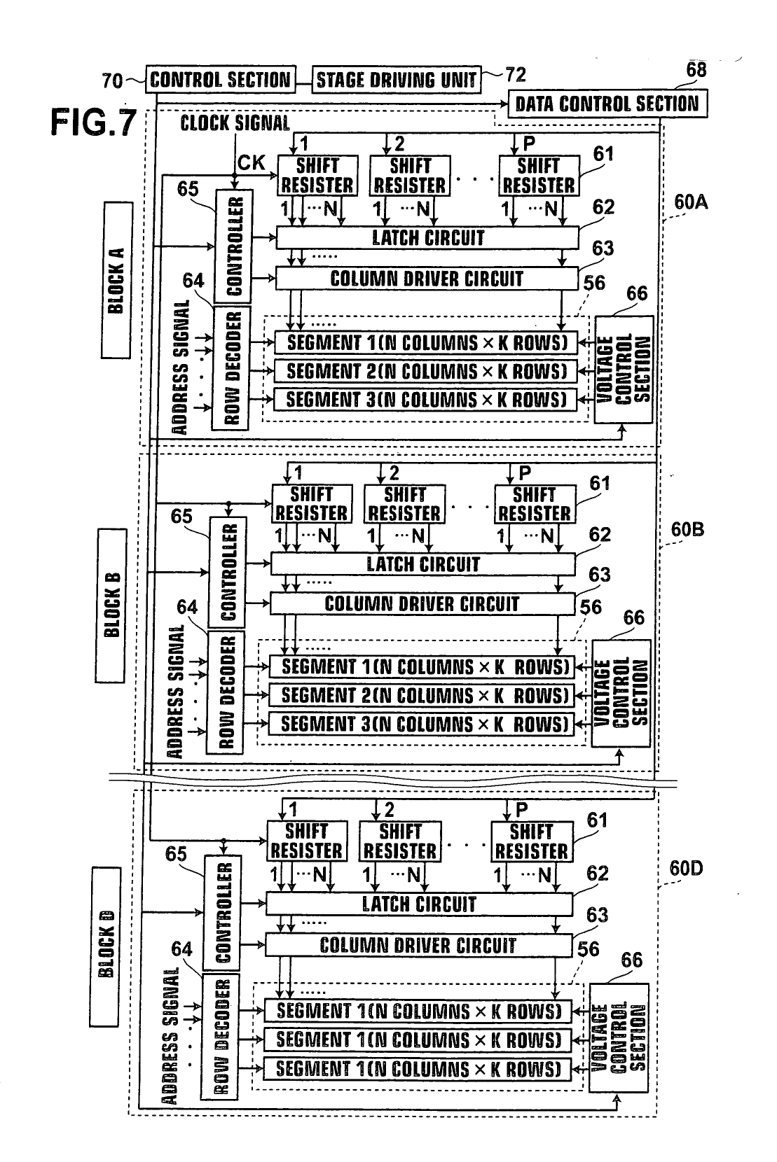

As shown in FIG. 7, each of the exposing heads 30 includes four control signal transfer sections 60A to 60D, each being provided for each of the blocks A to D of the DMD 36, for transferring the control signals to each of the blocks A to D in parallel. In FIG. 7, the control signal transfer section 60C is omitted. Further, in the present embodiment, the DMD 36 is divided into four blocks, but it may be divided into any number of blocks of not less than two.

As shown in FIG. 7, each of the control signal transfer sections 60A to 60D includes P shift resister circuits 61, a latch circuit 62, and a column driver circuit 63. A clock signal CK is inputted to each of the P shift register circuits 61 from a controller 65. One control signal is written into each of the P shift register circuits 61 simultaneously according to the clock signal CK. When N control signals are written into each of the P shift register circuits 61, the control signals of N×P for a single row are transferred to the latch circuit 62.

The control signals of a single row transferred to the latch circuit 62 are transferred as they are to the column driver circuit 63. The control signals for a single row outputted from the column driver circuit 63 are written into a predetermined row of the SRAM arrays 56. The predetermined row where the control signals are to be written is selected by a row decoder 64 based on an address signal.

While the control signals are latched by the latch circuit 62 and written into a predetermined row of the SRAM arrays 56 as described above, control signals for the next row are written into the shift register circuits 61.

The timings for writing the control signals into the shift register circuits 61, latch circuit 62, column driver circuit 63, and SRAM arrays 56 are controlled by the controller 65.

After the control signals are written into the SRAM arrays 56, control voltages according to the control signals written into the SRAM arrays 56 are applied to the respective electrode sections of the micro-mirrors 58 from a voltage control section 66, thereby each of the micro-mirrors is reset.

The voltage control section 66 provided for each of the blocks A to D is capable of outputting the control voltage to each of the three segments 1 to 3 provided by further dividing the micro-mirror rows in every K rows in each of the blocks A to D. In the present embodiment, each of the blocks A to D is divided into three segments, but it may be divided into any number of segments of not less than two.

Preferably, the number of segments N in each of the blocks satisfies the following formula.
N=Tₛᵣ/Tₜᵣ

where: Tₜᵣ: modulation time of each segment
Tₛᵣ: transfer time of control signals to each segment

The photolithography machine 10 of the present embodiment further includes a control section 70 for performing overall control of the photolithography machine, and a data control section 68 for outputting control signals to the control signal transfer sections 60A to 60D of each of the exposing heads 30. The writing operation of the control signals into the SRAM arrays 56 of the DMD 36, and driving of the micro-mirrors 58 are controlled by the control section 70. The control section 70 further drive controls a stage driving unit 72 that moves the moving stage 14.

Hereinafter, the operation of the photolithography machine 10 of the present embodiment will be described in detail.

First, image data corresponding to an image to be exposed on the photosensitive material 12 are generated by a predetermined data generating device (not shown), and outputted to the data control section 68. In the data control section 68, control signals to be outputted to each of the exposing heads 30 are generated based on the image data. In the photolithography machine 10 of the present embodiment, control signals are transferred to blocks A to D of the DMD 36 to drive the micro-mirrors 58 on a block by block basis, so that the control signals are also generated on a block by block basis.

While the control signals for each of the exposing heads 30 are generated by the data control section 68, a stage drive control signal is outputted to the stage driving unit 72 from the control section 70. The stage driving unit 72 moves the moving stage 14 along the guides 20 in the stage moving direction at an intended speed according to the stage drive control signal. When the stage 14 passes under the gate 22, the front edge of the photosensitive material 12 is detected by the sensors 26 attached to the gate 22. Then, the control signals are outputted to each of the exposing heads 30 from the data control section 68, and tracing is initiated by each of the exposing heads 30.

Hereinafter, drive control for the DMD 36 of each of the exposing heads 30 will be described in detail.

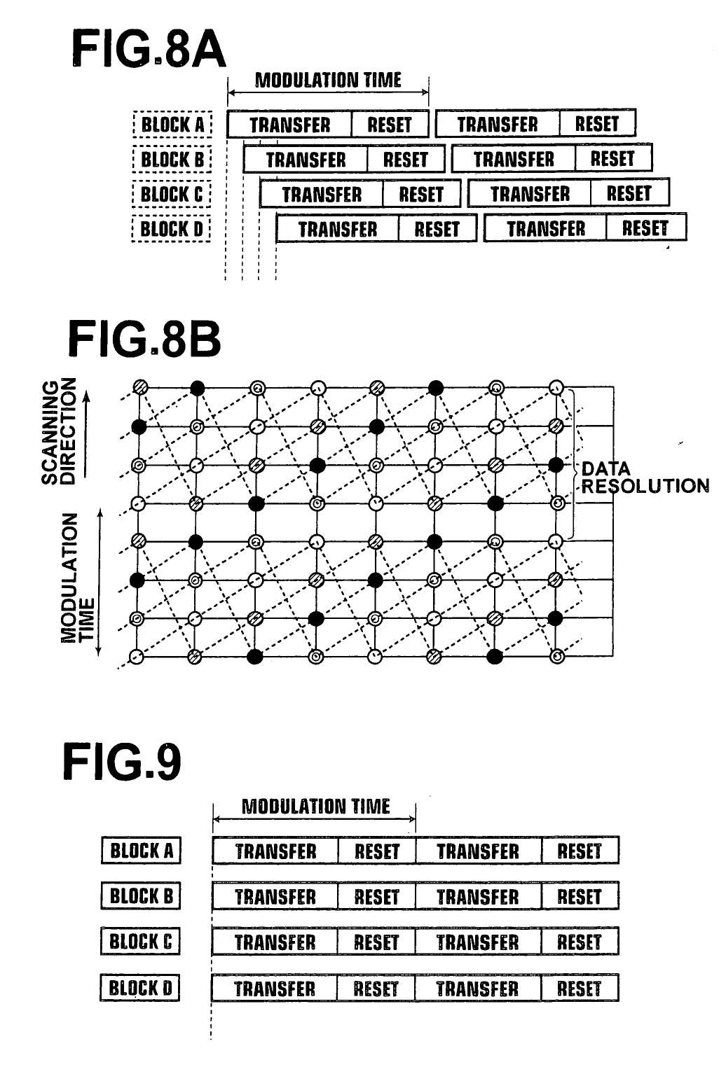

First, the control signals for each of the blocks A to D of the DMD 36 generated in the manner as described above are transferred to each of the control signal transfer sections 60A to 60D from the data control section 68 on a row by row basis. Here, the control signals are transferred to each of the blocks A to D at the timings shown in FIG. 8A. That is, the control signals are transferred to each of the Blocks A to D at the start timing which is sequentially delayed by a predetermined time as shown in FIG. 8A.

The control signals transferred in the manner described above are written into the SRAM arrays 56 in each of the blocks A to D by each of the control signal transfer sections 60A to 60D provided for each of the blocks A to D.

Then, as shown in FIG. 8A, the micro-mirrors are sequentially reset from those in the block to which the transfer of the control signals has been completed according to the control signals transferred thereto.

FIG. 8B shows example trace points produced on the photosensitive material 12 by transferring the control signals to each of the blocks A to D to reset the micro-mirrors 58 in each of the blocks A to D at the timing shown in FIG. 8A. In FIG. 8B, open circles indicate the trace points traced by the micro-mirrors 58 of the block A, double circles indicate those traced by the micro-mirrors 58 of the block B, filled circles indicate those traced by the micro-mirrors 58 of the block C, and hatched circles indicate those traced by the micro-mirrors 58 of the block D. The DMD 36 of the photolithography machine of the present embodiment, the micro-mirrors 58 in each of the blocks A to D are disposed to form a tilt angle of θ with the scanning direction so that each of the micro-mirrors in each of the blocks passes along the same scanning line, as shown in FIG. 8B.

For example, as shown in FIG. 8B, trace points traced by the micro-mirrors 58 in each of the blocks B to D may be disposed at regular intervals between trace points traced by the micro-mirrors 58 in the block A by sequentially delaying the timing of modulation in each of the blocks by a predetermined time as described above. The trace points in the blocks B to D produced during the modulation time of the block A shown in FIG. 8B are not those produced in a same frame, they are the points produced in the different frames. Here, the referent of “frame” means a process unit in which each of the blocks A to D is sequentially reset by sequentially transferring the control signals from the block A to block D.

Further, by controlling the moving speed of the photosensitive material 12 in the scanning direction, that is, the moving speed of the moving stage 14, trace points in each of the blocks B to D may also be disposed at regular intervals between the trace points in the block A, other than by sequentially delaying the timing of the modulation in each of the blocks A to D.

The moving speed of the moving stage 14 is preset in the control section 70 according to the time difference between each of the timings of the modulation in blocks A to D, and the stage driving unit 72 is controlled to move the moving stage 14 at the predetermined speed.

In the photolithography machine of the present embodiment, the timing of the modulation in each of the blocks A to D is sequentially delayed as described above. But, this is not necessarily required, and the control signals may be transferred to each of the blocks A to D simultaneously to reset micro-mirrors in each of the blocks A to D simultaneously, as shown in FIG. 9.

Further, in the present embodiment, the moving speed of the moving stage 14 may be preset first at an intended speed, then the timing of the modulation in each of the blocks A to D may be controlled or set according to the preset moving speed of the moving stage 14.

Still further, in the present embodiment, the timing of the modulation in each of the blocks A to D, and the moving speed of the moving stage 14 may be controlled such that trace points in each of the blocks A to D overlap with each other.

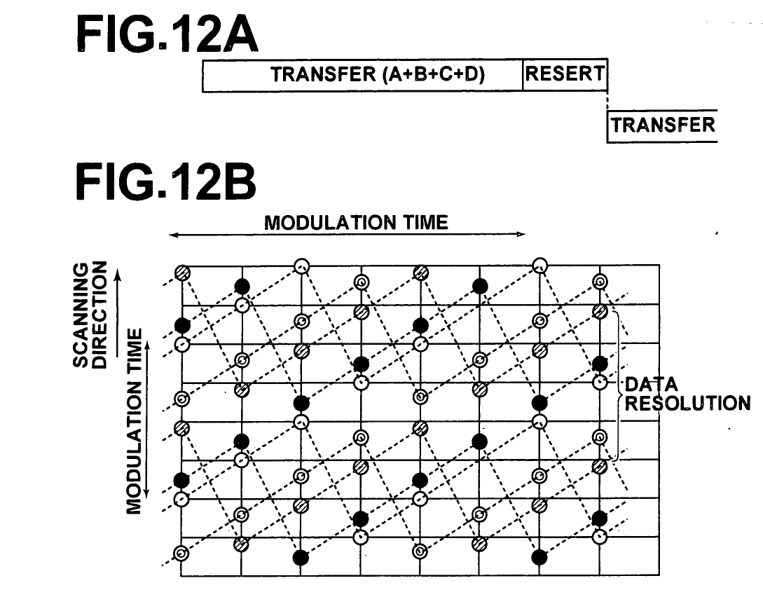

For comparison purpose, example trace points are shown in FIG. 12B when the resetting is implemented after control signals are transferred to all of the blocks A to D, unlike the case where the control signals are transferred to each of the blocks independently, and the resetting is implemented sequentially in each of the blocks A to D. When the resetting is implemented after control signals are transferred to all of the blocks A to D as shown in FIG. 12A, for example, the trace points traced by the micro-mirrors 58 of the blocks B to D are disposed randomly between the trace points traced by the micro-mirrors of the block A as shown in FIG. 12B. This is because the timing of tracing by each of the blocks A to D is determined solely by the modulation time regardless of the scanning speed.

In the photolithography machine of the present embodiment, the trace points are produced on the photosensitive material 12 by drive controlling the DMD 36 in each of the exposing heads 30 in the manner as described above.

Then, the photosensitive material 12 moves with the moving stage 14 at a constant speed. The photosensitive material 12 is scanned by the scanner 24 in the direction opposite to the stage moving direction, and a stripe-shaped exposed region 34 is formed by each of the exposing heads 30.

When the scanning of the photosensitive material 12 by the scanner 24 is completed, and rear edge of the photosensitive material 12 is detected by the sensors 26, the stage 14 is returned to the original position on the uppermost stream of the gate 22 by the stage driving unit 72 along the guides 20. Thereafter, the stage 14 is moved again along the guides 20 from the upstream to downstream of the gate 22 at a constant speed after a new photosensitive material 12 is placed thereon.

Hereinafter, a photolithography machine that employs a second embodiment of the tracing method and apparatus of the present invention will be described. The configuration of the photolithography machine of the present embodiment is similar to that of the first embodiment. It only differs from the first embodiment in the drive control method for drive controlling the DMD 36 in each of the exposing heads 30. Accordingly, only the drive control method for drive controlling the DMD 36 in each of the exposing heads 30 in the present embodiment will be described herein below.

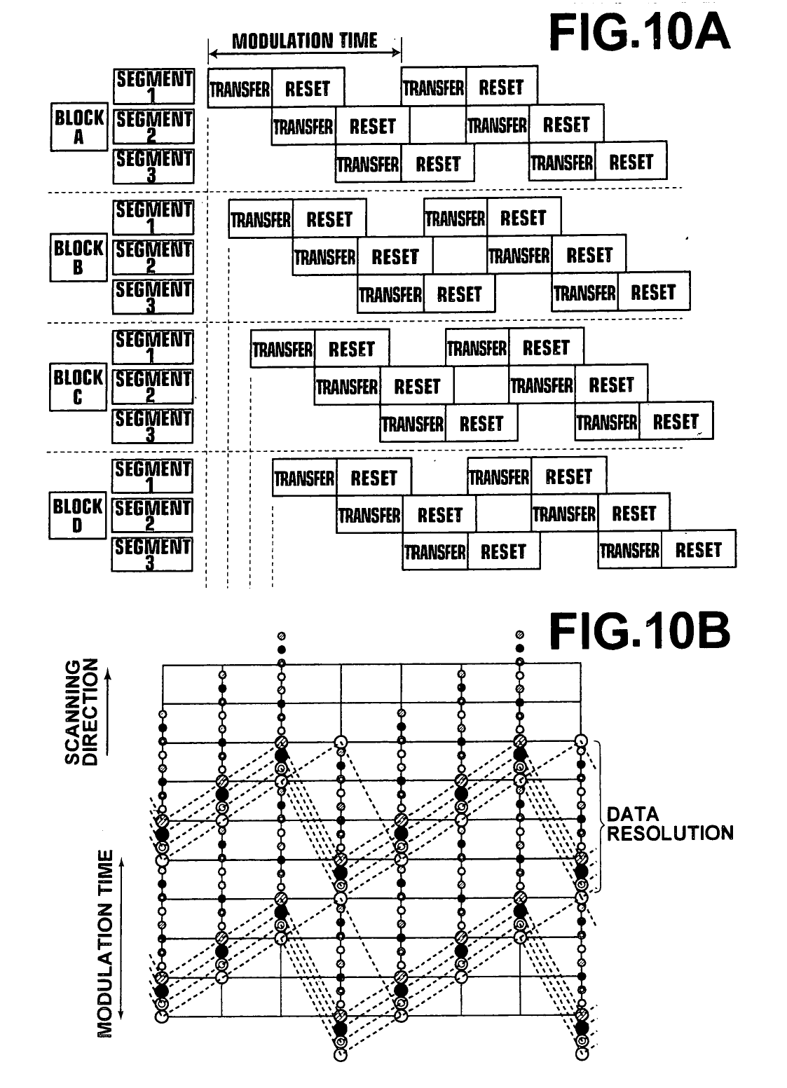

First, the control signals for each of the blocks A to D of the DMD 36 generated in the manner as described above are transferred to each of the control signal transfer sections 60A to 6D from the data control section 68 on a row by row basis, as in the first embodiment. Then, for example, in the block A, the control signals are sequentially transferred to each of the segments 1 to 3, and the micro-mirrors in each of the segments 1 to 3 are sequentially reset from the time when each of the transfers of the control signals to each of the segments 1 to 3 is completed, as shown in FIG. 10A. Likewise, in other blocks B to D, the control signals are sequentially transferred to each of the segments 1 to 3, and the micro-mirrors in each of the segments 1 to 3 are sequentially reset from the time when each of the transfers of the control signals to each of the segments 1 to 3 is completed. The control signals for each of the segments 1 to 3 in each of blocks A to D are transferred thereto by sequentially delayed by a predetermined time, as shown in FIG. 10A.

FIG. 10B shows example trace points produced on the photosensitive material 12 by transferring the control signals to each of the segments 1 to 3 in each of the blocks A to D to reset the micro-mirrors 58 in each of the segments 1 to 3 in each of the blocks A to D at the timing shown in FIG. 10A. In FIG. 10B, open circles indicate the trace points traced by the micro-mirrors 58 of the block A, double circles indicate those traced by the micro-mirrors 58 of the block B, filled circles indicate those traced by the micro-mirrors 58 of the block C, and hatched circles indicate those traced by the micro-mirrors 58 of the block D.

By sequentially transferring the control signals to each of the segments 1 to 3 in each of the blocks A to D to sequentially implement the resetting, and sequentially delaying the reset timing of each of the segments 1 to 3 in each of the blocks A to D by a predetermined time, for example, trace points traced by the micro-mirrors 58 in each of the blocks B to D may be disposed at regular intervals between trace points traced by the micro-mirrors 58 in the block A as shown in FIG. 10B, and tracing of the trace points by the micro-mirrors 58 in each of the blocks A to D may be implemented three times in repeated fashion while the photosensitive material 12 moves by the distance which corresponds to the modulation time shown in FIG. 10B. Here, the reset timing of each of the segments 1 to 3 may be controlled or set directly. Alternatively, the reset timing of each of the segments 1 to 3 in each of the blocks A to D may be controlled or set through control of the reset timing of each of the blocks A to D. The trace points produced by each of the blocks A to D during the modulation time shown in FIG. 10B are not those produced in a same frame, they are the points produced in different frames. Further, the moving speed of the photosensitive material 12 in the scanning direction, that is, the moving speed of the moving stage 14 may be controlled according to the time difference between each of the timings of the modulation in blocks A to D as in the first embodiment in order to dispose trace points in each of the blocks B to D at regular intervals between the trace points in the block A.

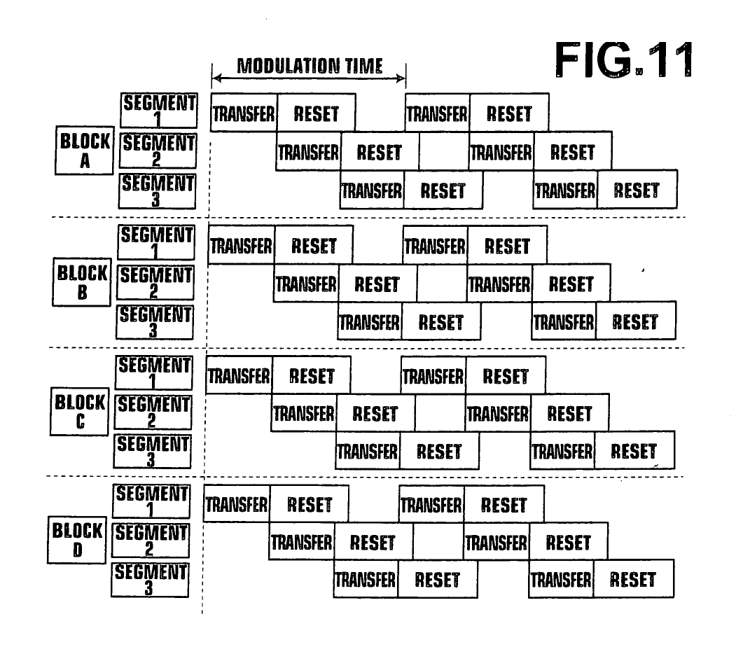

In the photolithography machine in the present embodiment, the timing of the modulation in each of the corresponding segments 1 to 3 in each of the blocks A to D is sequentially delayed as described above. But, this is not necessarily required, and the control signals may be transferred to each of the corresponding segments 1 to 3 in each of the blocks A to D simultaneously to reset micro-mirrors in each of the corresponding segments 1 to 3 in each of the blocks A to D simultaneously, as shown in FIG. 11.

Further, in the present embodiment, the timing of the modulation in each of the segments 1 to 3 in each of the blocks A to D, and the moving speed of the moving stage 14 may be controlled such that trace points traced by each of the segments in each of the blocks A to D overlap with each other.

Further, in the embodiments described above, the DMD 36 is divided into the plurality of blocks A to Din the scanning direction. But, the division method is not limited to this. For example, it may be divided into a plurality of blocks in a direction which is orthogonal to the scanning direction, and the control signals may be transferred to each of the blocks in parallel. In addition, each of the blocks provided in the manner as described above may be further subdivided into segments in the scanning direction, or a direction which is orthogonal to the scanning direction, and the transfer of the control signals and modulation may be implemented on a segment by segment basis as in the embodiment described above.

Still further, in the embodiments described above, a photolithography machine that includes a DMD as the spatial optical modulation device has been illustrated. A transmissive spatial optical modulation device may also be used beside such reflective spatial optical modulation device.

Further, in the embodiments described above, a so-called flatbed photolithography machine has been illustrated. But, the present invention may also be applied to a so-called outer drum photolithography machine having a drum on which the photosensitive material is rolled.

Still further, in the embodiments described above, the photosensitive material 12, which is the object of exposure, may be a printed board or a display filter. Further, the photosensitive material 12 may be of sheet-like form or continuous length (such as flexible substrate or the like).

The tracing method and apparatus of the present invention may also be applied to trace control of an ink-jet printer or the like. For example, the trace points to be produced through jetting of ink may be controlled in the similar manner as described in the present invention. That is, the tracing elements of the present invention may be replaced by the elements that produce trace points through jetting of ink or the like.

1-28. (canceled)

29. A tracing method using a spatial optical modulation device constituted by multitudes of tracing elements disposed thereon two-dimensionally for modulating inputted light according to control signals transferred in accordance with tracing information, in which tracing is performed by implementing the modulation through transferring the control signals to the tracing elements of the spatial optical modulation device, and moving the spatial optical modulation device in a predetermined scanning direction relative to a tracing surface, wherein:
the spatial optical modulation device is divided into a plurality of blocks in the scanning direction; and
the control signals for each of the plurality of blocks are transferred thereto in parallel.

30. The tracing method according to claim 29, wherein the arrangement of each of trace regions on the tracing surface corresponding to each of the blocks is controlled by causing the modulation to be implemented independently by each of the blocks, and controlling the timing of the modulation implemented independently by each of the blocks, and/or the relative moving speed of the spatial optical modulation device in the scanning direction.

31. The tracing method according to claim 30, wherein the tracing is performed first by the block disposed downstream, then by the block or blocks disposed upstream in the scanning direction with respect to the tracing surface.

32. The tracing method according to claim 30, wherein the timing of the modulation implemented independently by each of the blocks, and/or the relative moving speed of the spatial optical modulation device in the scanning direction are controlled such that the trace region corresponding to the block disposed downstream, and the trace region or regions corresponding to the block or blocks disposed upstream in the scanning direction with respect to the tracing surface are overlap with each other.

33. The tracing method according to claim 30, wherein the timing of the modulation implemented independently by each of the blocks, and/or the relative moving speed of the spatial optical modulation device in the scanning direction are controlled such that trace points in the trace region or regions corresponding to the block or blocks disposed upstream are disposed between trace points arranged in the scanning direction in the trace region corresponding to the block disposed downstream in the scanning direction with respect to the tracing surface.

34. The tracing method according to claim 33, wherein the timing of the modulation implemented independently by each of the blocks, and/or the relative moving speed of the spatial optical modulation device in the scanning direction are controlled such that trace points in each of the trace regions corresponding to each of the blocks are disposed at regular intervals in the scanning direction.

35. The tracing method according to claim 29, wherein:
each of the blocks is further subdivided into a plurality of segments; and
the control signals are sequentially transferred to each of the segments in each of the blocks, and the modulation is implemented sequentially by each of the segments from the time when each of the transfers of the control signals is completed.

36. The tracing method according to claim 35, wherein arrangement of each of segment trace regions on the tracing surface corresponding to each of the segments in each of the blocks is controlled by controlling the timing of the modulation in the segments in each of the blocks, and/or the relative moving speed of the spatial optical modulation device in the scanning direction.

37. The tracing method according to claim 36, wherein the tracing is performed first by the segments in the block disposed downstream, then by the segments in the block or blocks disposed upstream in the scanning direction with respect to the tracing surface.

38. The tracing method according to claim 36, wherein the timing of the modulation in the segments in each of the blocks, and/or the relative moving speed of the spatial optical modulation device in the scanning direction are controlled such that the segment trace regions corresponding to the segments in the block disposed downstream, and the segment trace regions corresponding to the segments in the block or blocks disposed upstream in the scanning direction with respect to the tracing surface are overlap with each other.

39. The tracing method according to claim 36, wherein the timing of the modulation in the segments in each of the blocks, and/or the relative moving speed of the spatial optical modulation device in the scanning direction are controlled such that trace points in the segment trace regions corresponding to the segments in the block or blocks disposed upstream are disposed between trace points arranged in the scanning direction in the segment trace regions corresponding to the segments in the block disposed downstream in the scanning direction with respect to the tracing surface.

40. The tracing method according to claim 39, wherein the timing of the modulation in the segments in each of the blocks, and/or the relative moving speed of the spatial optical modulation device in the scanning direction are controlled such that trace points in each of the segment trace regions corresponding to each of the segments in each of the blocks are disposed at regular intervals in the scanning direction.

41. The tracing method according to claim 35, wherein the number of segments N in each of the blocks satisfies the following formula.
N=Tₛᵣ/Tₜᵣ
where: Tₜᵣ: modulation time of each segment
Tₛᵣ: transfer time of control signals to each segment

42. A tracing method using a spatial optical modulation device constituted by multitudes of tracing elements disposed thereon two-dimensionally for modulating inputted light according to control signals transferred in accordance with tracing information, in which tracing is performed by implementing the modulation through transferring the control signals to the tracing elements of the spatial optical modulation device, and moving the spatial optical modulation device in a predetermined scanning direction relative to a tracing surface, wherein:
the spatial optical modulation device is divided into a plurality of blocks; and
the control signals for each of the plurality of blocks are transferred thereto in parallel.

43. A tracing apparatus comprising:
a spatial optical modulation device constituted by multitudes of tracing elements disposed thereon two-dimensionally for modulating inputted light according to control signals transferred in accordance with tracing information;
a moving means for moving the spatial optical modulation device in a predetermined scanning direction relative to a tracing surface; and
a control means for causing the tracing elements of the spatial optical modulation device to implement the modulation by transferring the control signals thereto, and controlling the relative moving speed of the spatial optical modulation device in the scanning direction through controlling the moving means, wherein:
the spatial optical modulation device is divided into a plurality of blocks in the scanning direction; and
the control means includes a plurality of control signal transfer sections, each being provided for each of the blocks, for transferring the control signals to each of the blocks in parallel.

44. The tracing apparatus according to claim 43, wherein the control means is configured to control the arrangement of each of trace regions on the tracing surface corresponding to each of the blocks by causing the modulation to be implemented independently by each of the blocks, and controlling the timing of the modulation implemented independently by each of the blocks, and/or the relative moving speed of the spatial optical modulation device in the scanning direction.

45. The tracing apparatus according to claim 44, wherein the control means is configured to cause the tracing to be performed first by the block disposed downstream, then by the block or blocks disposed upstream in the scanning direction with respect to the tracing surface.

46. The tracing apparatus according to claim 44, wherein the control means is configured to control the timing of the modulation implemented independently by each of the blocks, and/or the relative moving speed of the spatial optical modulation device in the scanning direction such that the trace region corresponding to the block disposed downstream, and the trace region or regions corresponding to the block or blocks disposed upstream in the scanning direction with respect to the tracing surface are overlap with each other.

47. The tracing apparatus according to claim 44, wherein the control means is configured to control the timing of the modulation implemented independently by each of the blocks, and/or the relative moving speed of the spatial optical modulation device in the scanning direction such that trace points in the trace region or regions corresponding to the block or blocks disposed upstream are disposed between trace points arranged in the scanning direction in the trace region corresponding to the block disposed downstream in the scanning direction with respect to the tracing surface.

48. The tracing apparatus according to claim 47, wherein the control means is configured to control the timing of the modulation implemented independently by each of the blocks, and/or the relative moving speed of the spatial optical modulation device in the scanning direction such that trace points in each of the trace regions corresponding to each of the blocks are disposed at regular intervals in the scanning direction.

49. The tracing apparatus according to claim 43, wherein:
each of the blocks is further subdivided into a plurality of segments; and
the control signals are sequentially transferred to each of the segments in each of the blocks, and the modulation is implemented sequentially by each of the segments from the time when each of the transfers of the control signals is completed.

50. The tracing apparatus according to claim 49, wherein the control means is configured to control arrangement of each of segment trace regions on the tracing surface corresponding to each of the segments in each of the blocks by controlling the timing of the modulation in the segments in each of the blocks, and/or the relative moving speed of the spatial optical modulation device in the scanning direction.

51. The tracing apparatus according to claim 50, wherein the control means is configured to cause the tracing to be performed first by the segments in the block disposed downstream, then by the segments in the block or blocks disposed upstream in the scanning direction with respect to the tracing surface.

52. The tracing apparatus according to claim 50, wherein the control means is configured to control the timing of the modulation in the segments in each of the blocks, and/or the relative moving speed of the spatial optical modulation device in the scanning direction such that the segment trace regions corresponding to the segments in the block disposed downstream, and the segment trace regions corresponding to the segments in the block or blocks disposed upstream in the scanning direction with respect to the tracing surface are overlap with each other.

53. The tracing apparatus according to claim 50, wherein the control means is configured to control the timing of the modulation in the segments in each of the blocks, and/or the relative moving speed of the spatial optical modulation device in the scanning direction such that trace points in the segment trace regions corresponding to the segments in the block or blocks disposed upstream are disposed between trace points arranged in the scanning direction in the segment trace regions corresponding to the segments in the block disposed downstream in the scanning direction with respect to the tracing surface.

54. The tracing apparatus according to claim 53, wherein the control means is configured to control the timing of the modulation in the segments in each of the blocks, and/or the relative moving speed of the spatial optical modulation device in the scanning direction such that trace points in each of the segment trace regions corresponding to each of the segments in each of the blocks are disposed at regular intervals in the scanning direction.

55. The tracing apparatus according to claim 49, wherein the number of segments N in each of the blocks satisfies the following formula.
N=Tₛᵣ/Tₜᵣ
where: Tₜᵣ: modulation time of each segment
Tₛᵣ: transfer time of control signals to each segment

56. A tracing apparatus comprising:
a spatial optical modulation device constituted by multitudes of tracing elements disposed thereon two-dimensionally for modulating inputted light according to control signals transferred in accordance with tracing information;
a moving means for moving the spatial optical modulation device in a predetermined scanning direction relative to a tracing surface; and
a control means for causing the tracing elements of the spatial optical modulation device to implement the modulation by transferring the control signals thereto, and controlling the relative moving speed of the spatial optical modulation device in the scanning direction through controlling the moving means, wherein:
the spatial optical modulation device is divided into a plurality of blocks; and
the control means includes a plurality of control signal transfer sections, each being provided for each of the blocks, for transferring the control signals to each of the blocks in parallel.
